(19) United States
(12) Patent Application Publication
(10) Pub. No.: US 2010/0216312 A1
(43) Pub. Date: Aug. 26, 2010

(54) RESIST REMOVING METHOD, SEMICONDUCTOR MANUFACTURING METHOD, AND RESIST REMOVING APPARATUS

(75) Inventors: Hiroaki Yamamoto, Osaka (JP); Takashi Minamihonoki, Osaka (JP); Shinji Masuoka, Osaka (JP); Yoshishige Ninomiya, Osaka (JP); Kyota Morihira, Kanagawa (JP)

Correspondence Address: EDWARDS ANGELL PALMER & DODGE LLP, P.O. BOX 55874, BOSTON, MA, 02205, US

(73) Assignees: SHARP KABUSHIKI KAISHA, Osaka (JP); AQUA SCIENCE CORPORATION, Kanagawa (JP)

(21) Appl. No.: 12/601,913

(22) PCT Filed: May 23, 2008
(86) PCT No.: PCT/JP2008/059786

§ 371 Date: Apr. 8, 2010

(30) Foreign Application Priority Data
Jun. 1, 2007 (JP) 2007-146396

(51) Int. Cl. H01L 21/3065

(52) U.S. Cl. 438/725; 156/345.26; 156/345.1; 257/E21.218

(57) ABSTRACT

This invention provides a resist removing apparatus for removing a resist comprising a deteriorated layer and an undeteriorated layer from a substrate. The apparatus carries out the step of bringing radicals, reduced by subjecting any one of or a mixture of two or more of nitrogen, oxygen, hydrogen, and steam to plasma treatment under a low pressure, into contact with the substrate to remove the resist, and the step of bringing ozone water into contact with the substrate to remove the resist. In the step of removing the resist by radicals, a large part of the undeteriorated layer is allowed to remain by regulating the radical contact time depending upon conditions for the formation of the deteriorated layer on the resist surface. Alternatively, a large part of the undeteriorated layer may be allowed to remain by conducting process control according to the results of analysis of a reactant gas discharged during the removal of the resist.

### TECHNICAL FIELD

The present invention relates to a method and an apparatus for removal of resist after formation of a pattern from a substrate, for use with a substrate—such as a semiconductor wafer, a substrate for a liquid crystal panel, and an electronic circuit substrate—on which a pattern is formed by use of resist

### BACKGROUND ART

Of the different types of substrate mentioned above, a semiconductor wafer will now be taken up as an example for description of a manufacturing process. A thin film (oxide film) is formed on the surface of the substrate by a chemical vapor deposition (CVD) method, an oxidation method, a sputtering method, or the like. Then photoresist is applied on the thin film, and the result is subjected to exposure and development to form a pattern of resist. With the resist pattern used as a protective film, etching is performed to remove the unnecessary part of the thin film, and then ion injection is performed. After ion injection, the resist, which is now unnecessary, needs to be removed. In conventional removal methods, it is common to remove resist by decomposing or dissolving it with various chemicals, such as a mixture liquid of an acid (e.g., sulfuric acid) and a peroxide, or an organic solvent. With such resist as has been greatly degraded as a result of high-concentration ion injection and thus cannot be removed with a chemical alone, low-pressure plasma ashing may be used together.

Resist removal using a chemical requires management of the chemical with due care. In a case where a strong acid such as sulfuric acid is used as a chemical, the chemical itself is a hazardous substance, and accordingly great care is needed in its safe handling and management. The used chemical needs to be subjected to waste treatment, which itself poses a tricky problem in view of environmental contamination that may result. From the viewpoints of safety and environmental conservation, therefore, resist removal without using a chemical is being sought.

One example of resist removal without using a chemical is a method using ozone (O₃). According to it, a substrate is exposed to gaseous ozone or a solution of ozone to decompose resist by oxidization. This method allows easy waste treatment, and is satisfactory in terms of safety and environmental conservation.

Disadvantageously, however, resist removal with ozone takes time. Not only does it take time, ozone's cleaning action is insufficient, and may even be simply powerless, for removal of resist that has been greatly degraded as a result of thermal polymerization or crosslinking reaction. There have accordingly be made various proposals attempting to achieve enhanced removal performance by combining different resist removal methods together while sticking to the principle of not using a chemical.

According to the method described in Patent Document 1 listed below, under a pressure close to the atmospheric pressure, resist is bombarded with a plasma-treated gas, and the resist is then put in contact with steam, so that the resist exfoliates, and is thereby removed, from the substrate.

According to the method described in Patent Document 2 listed below, after dry ashing, resist remaining on a substrate is subjected to wet exfoliation using ozone water excited with ultraviolet rays.

According to the method described in Patent Document 3 listed below, a superficial degraded layer of resist is removed by plasma treatment under a first pressure, and then an undegraded part of the resist is removed by plasma treatment under a second pressure higher than the first pressure.

According to the method described in Patent Document 4 listed below, after resist is removed by ashing achieved by plasma treatment, a residue containing dopants is removed by ashing at a higher temperature.

### Patent Document 1: JP-2006-49712

### Patent Document 2: JP-2002-353196

### Patent Document 3: JP-2005-236012

### Patent Document 4: JP-2000-286248

### DISCLOSURE OF THE INVENTION

### Problems to be Solved by the Invention

The above-mentioned conventional resist removal methods using no chemical are, however, unsatisfactory in the following respects. The method described in Patent Document 1 is not capable of surface modification of a degraded layer formed at the surface of resist by ion injection; even if it were, it would take undue time. This hampers progress of decomposition that follows, and makes it impossible to complete resist removal in a practically acceptable length of time, necessitating post-treatment. The method described in Patent Document 2 degrades resist with heat in dry ashing, making the resist prone to be left unremoved. It also requires ultraviolet ray generator for activation of ozone water. The method described in Patent Document 3 requires addition of a gas containing fluorine, and thus having a high environmental load, for removal of a residue after low-pressure plasma treatment.

To overcome the inconveniences mentioned above, an object of the present invention is to provide a method and an apparatus for removal of resist that use no chemical and that have little effect on the environment, more specifically those that allow removal of surface-degraded resist from a substrate in a practicable, rational manner.

### Means for Solving the Problem

To achieve the above object, according to the invention, a resist removal method for removal of surface-degraded resist from a substrate includes: a step of removing the resist by putting, in contact with the substrate, radicals generated through plasma treatment of one of nitrogen, oxygen, hydrogen, and water vapor or a mixed gas of any combination thereof under a low pressure; and a step of removing the resist by putting ozone water in contact with the substrate.

With this scheme, by combined use of radicals and ozone water, it is possible to effectively remove the surface-degraded resist, including both a degraded layer and an undegraded layer, from the substrate.

According to the invention, a resist removal method for removal of surface-degraded resist from a substrate includes: a step of removing the resist by putting, in contact with the substrate, radicals generated through plasma treatment of a gas whose molecule contains a hydrogen atom; and a step of removing the resist by putting ozone water in contact with the substrate.

With this scheme, plasma treatment generates H radicals and OH radicals; by combined use of those radicals and ozone water, it is possible to effectively remove the surface-degraded resist, including both a degraded layer and an undegraded layer, from the substrate.

According to the invention, in the resist removal methods described above, the step of resist removal using the radicals precedes the step of resist removal using the ozone water.

With this scheme, the step of resist removal using the radicals, which is effective in removal of a degraded layer at the surface of the resist, is followed by the step of resist removal using the ozone water, which is effective in removal of an undegraded layer inside the resist. Thus, it is possible to rationally remove the surface-degraded resist, including both a degraded layer and an undegraded layer.

According to the invention, in the resist removal methods described above, the step of resist removal using the radicals is mainly for removing a degraded layer at the surface of the resist, and the step of resist removal using the ozone water is for removing an undegraded layer inside the resist.

With this scheme, by exploiting differences in properties between the radicals and the ozone water, it is possible to effectively remove the surface-degraded resist, including both a degraded layer and an undegraded layer, from the substrate.

According to the invention, in the resist removal methods described above, in the step of resist removal using the radicals, the length of time of contact with the radicals is controlled according to a condition of formation of the degraded layer at the surface of the resist such that a large part of the undegraded layer is left unremoved.

With this scheme, it is possible to enhance the time efficiency of the process without unnecessarily prolonging the time of contact with the radicals.

According to the invention, in the resist removal methods described above, in the step of resist removal using the radicals, process control is performed according to the result of analysis of the reacted gas exhausted during resist removal such that a large part of the undegraded layer is left unremoved.

With this scheme, it is possible to enhance the time efficiency of the process by stopping contact with the radicals with proper timing.

According to the invention, in the resist removal methods described above, in the step of resist removal using the radicals, the temperature of the substrate is kept equal to or higher than the temperature at or above which an activation energy enabling removal of the degraded layer using radicals can be supplied but lower than the temperature at which popping occurs.

With this scheme, it is possible to promote removal of the resist without causing popping.

According to the invention, in the resist removal methods described above, in the step of resist removal using the radicals, an ion shielding plate is disposed between a plasma treatment portion and the substrate to prevent ions in the generated plasma from making contact with the substrate.

With this scheme, it is possible to suppress a rise in the temperature of the substrate, and thereby to prevent popping from occurring.

According to the invention, in the resist removal methods described above, in the step of resist removal using the radicals, the pressure of contact between the substrate and the radicals is 6.6 Pa or more.

With this scheme, it is possible to make the radicals act effectively, thereby to enhance the degraded layer removal performance.

According to the invention, in the resist removal methods described above, in the step of resist removal using the radicals, the pressure of contact between the substrate and the radicals is 667 Pa or less.

With this scheme, it is possible to make the radicals act effectively, thereby to enhance the degraded layer removal performance.

According to the invention, in the resist removal methods described above, in the step of resist removal using the ozone water, the ozone water is heated and used.

With this scheme, it is possible to increase the reactivity of the ozone water, and thereby to effectively remove the undegraded layer.

According to the invention, a semiconductor manufacturing method involves cleaning with hydrogen fluoride a substrate that has gone through any of the resist removal methods described above, and then sending it to a diffusion process.

With this scheme, it is possible to realize a semiconductor manufacturing method that uses little chemicals and that has little effect on the environment.

According to the invention, a resist removal apparatus for removal of surface-degraded resist from a substrate is provided with: a gas supply portion that supplies one of nitrogen, oxygen, hydrogen, and water vapor or a mixed gas of any combination thereof; a plasma treatment portion that subjects the gas supplied from the gas supply portion to plasma treatment to generate radicals; a degraded layer removal portion that puts the radicals in contact with the substrate to mainly remove a degraded layer at the surface of the resist; an ozone water generation portion; and an undegraded layer removal portion that puts ozone water supplied from the ozone water generation portion in contact with the substrate to mainly remove an undegraded layer of the resist.

With this scheme, by combined use of radicals and ozone water, and through their appropriate use according to their respective properties, it is possible to effectively remove the surface-degraded resist, including both a degraded layer and an undegraded layer, from the substrate.

According to the invention, a resist removal apparatus for removal of surface-degraded resist from a substrate is provided with: a gas supply portion that supplies a gas whose molecule contains a hydrogen atom; a plasma treatment portion that subjects the gas supplied from the gas supply portion to plasma treatment to generate radicals; a degraded layer removal portion that puts the radicals in contact with the substrate to mainly remove the degraded layer at the surface of the resist; an ozone water generation portion; and an undegraded layer removal portion that puts ozone water supplied from the ozone water generation portion in contact with the substrate to mainly remove an undegraded layer of the resist.

With this scheme, by combined use of ozone water with H radicals and OH radicals generated by plasma treatment, and through their appropriate use according to their respective properties, it is possible to effectively remove the surface-degraded resist, including both a degraded layer and an undegraded layer, from the substrate.

According to the invention, in the resist removal apparatuses described above, the operation of the degraded layer removal portion is controlled by controlling the length of time of contact with the radicals according to a condition of formation of the degraded layer at the surface of the resist or by performing process control according to the result of analysis of the reacted gas exhausted during resist removal.

With this scheme, it is possible to rationally control the operation of the degraded layer removal portion, and thereby to increase the operation efficiency of the apparatus.

According to the invention, in the resist removal apparatuses described above, the temperature of the substrate in the degraded layer removal portion is kept equal to or higher than the temperature at or above which an activation energy enabling removal of the degraded layer using radicals can be supplied but lower than the temperature at which popping occurs.

With this scheme, it is possible to promote removal of the resist without causing popping.

According to the invention, in the resist removal apparatuses described above, an ion shielding plate is disposed between the plasma treatment portion and the substrate in the degraded layer removal portion to prevent ions in the generated plasma from making contact with the substrate.

With this scheme, it is possible to suppress a rise in the temperature of the substrate resulting from contact with ions, and thereby to prevent popping from occurring.

According to the invention, in the resist removal apparatuses described above, there is provided a temperature regulator that regulates the temperature of the ozone water supplied to the undegraded layer removal portion.

With this scheme, it is possible to increase the reactivity of the ozone water, and thereby to effectively remove the undegraded layer.

### ADVANTAGES OF THE INVENTION

According to the present invention, it is possible to remove surface-degraded resist from a substrate efficiently in short time without use of conventionally used chemicals, such as those hazardous to use and to store and having a high environmental load like heated sulfuric acid, and without use of a gas containing fluorine and having a high environmental load.

### BRIEF DESCRIPTION OF DRAWINGS

FIG. 1 Conceptual diagrams of a resist removal process.

FIG. 2 A conceptual diagram of a resist removal apparatus.

FIG. 3 A plan view of an ion shielding plate.

FIG. 4 Photographs of popping as actually occurred in a resist pattern.

FIG. 5 A graph showing a relationship between the degree of vacuum in a vacuum chamber and the temperature of a substrate.

FIG. 6 A graph showing a relationship between the temperature of ozone water and the removal time of an undegraded layer.

FIG. 7 Photographs of actual removal of a degraded layer and an undegraded layer.

FIG. 8 Photographs of resist removal experiments conducted with an apparatus embodying the invention.

FIG. 9 Photographs of resist removal experiments conducted, by use of water vapor, with an apparatus embodying the invention.

### LIST OF REFERENCE SYMBOLS

1 substrate
2 resist
2a degraded layer
2b undegraded layer
10 resist removal apparatus
11 degraded layer removal unit
12 undegraded layer removal unit
20 vacuum chamber
21 vacuum pump
22 gas analyzer
26 plasma treatment portion
27 degraded layer removal portion
30 substrate temperature regulator
40 undegraded layer removal portion
42 ozone water feed nozzle
43 ozone water generation portion
44 ozone water temperature regulator

### BEST MODE FOR CARRYING OUT THE INVENTION

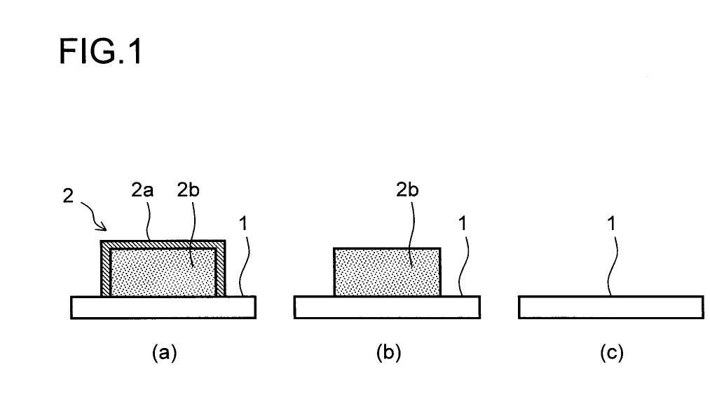

An embodiment of the present invention will be described below with reference to the accompanying drawings. FIG. 1(a) shows resist 2 formed on the surface of a substrate 1. The resist 2 has, at its surface, a degraded layer 2a and, inside it, an undegraded layer 2b. From this resist 2, the degraded layer 2a is removed as shown in FIG. 1(b), and then the undegraded layer 2b is removed as well as shown in FIG. 1(c).

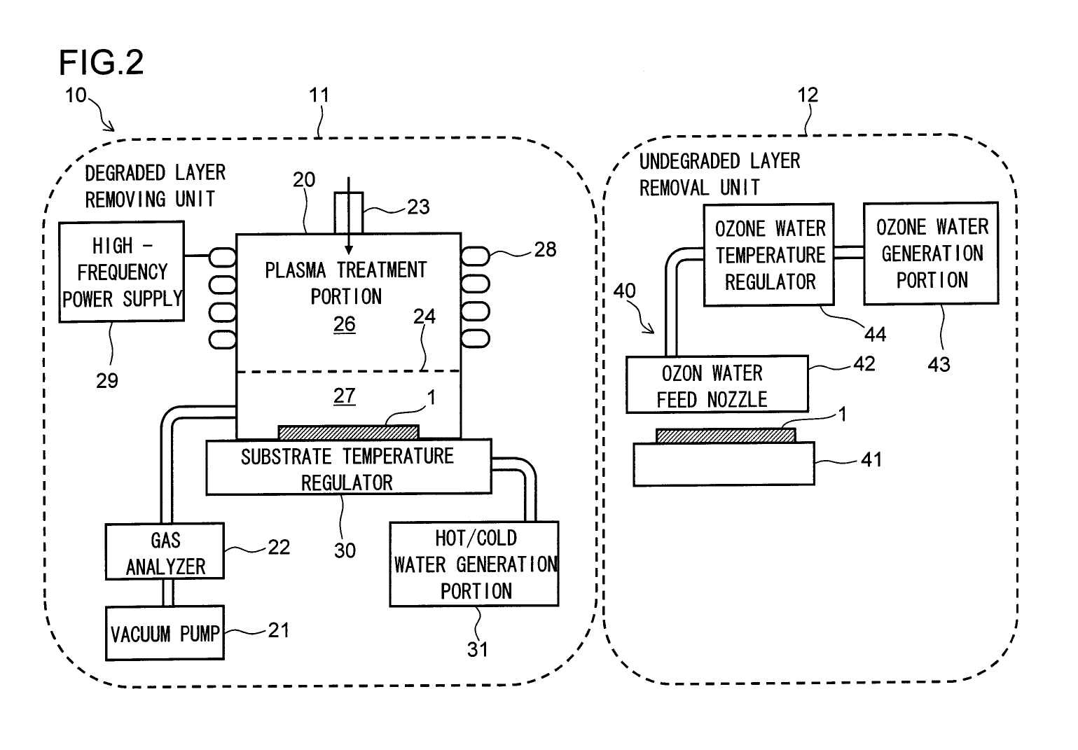

The resist removal process is performed by a resist removing apparatus 10, which is composed of, as shown in FIG. 2, a degraded layer removing unit 11 and an undegraded layer removal unit 12. The configuration of the degraded layer removing unit 11 and that of the undegraded layer removal unit 12 will be described one by one below.

The degraded layer removing unit 11 is provided with a vacuum chamber 20. To the vacuum chamber 20, a vacuum pump 21 is connected via a gas analyzer 22. The vacuum chamber 20 is, in the ceiling thereof, provided with a gas introduction port 23. The gas introduction port 23 is connected to an unillustrated gas supply portion.

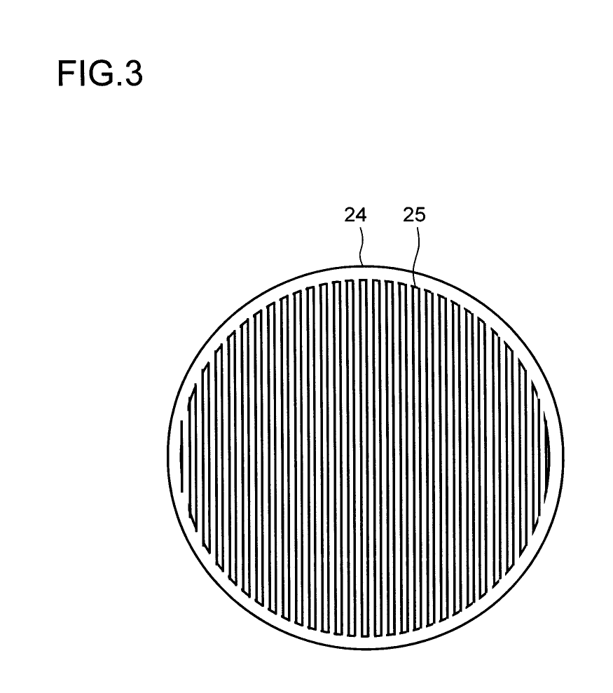

The inside of the vacuum chamber 20 is divided into an upper and a lower part by an ion shielding plate 24. The ion shielding plate 24 is, as shown in FIG. 3, a plate of quartz having, formed parallel to one another, a large number of radical passage openings 25 in the form of slits each with a width of about 2 mm. The intervals between adjacent radical passage openings 25 also are about 2 mm each. The space above the ion shielding plate 24 is a plasma treatment portion 26, and the space below the ion shielding plate 24 is a degraded layer removal portion 27.

The plasma treatment portion 26 is surrounded by a high-frequency coil 28. The high-frequency coil 28 is supplied with an electric current of a predetermined frequency from a high-frequency power supply 29.

A radical generation mechanism other than one relying on a high frequency may instead be adopted. Examples include those relying on ECR (electron cyclotron resonance) plasma, ICP (inductively coupled plasma), and helicon wave plasma.

At the bottom of the degraded layer removal portion 27, a substrate temperature regulator 30 is provided. The substrate temperature regulator 30 is heated by hot water, and cooled by cold water, supplied from a hot/cold water generation portion 31 for temperature control. The substrate temperature regulator 30 keeps the temperature of the substrate 1 placed on it at a predetermined value.

The undegraded layer removal unit 12 is provided with an undegraded layer removal portion 40. The undegraded layer removal portion 40 is provided with a table 41 on which the substrate 1 is placed, and an ozone water feed nozzle 42 that feeds ozone water dropwise onto the substrate 1 on the table 41. To the ozone water feed nozzle 42, an ozone water generation portion 43 is connected via an ozone water temperature regulator 44.

In the resist removing apparatus 10, the resist removal process proceeds as follows. First, the substrate 1 is placed in the degraded layer removal portion 27 of the degraded layer removing unit 11. In the embodiment under discussion, the substrate 1 is assumed to be a semiconductor wafer. The resist 2 formed on the substrate 1 has its surface degraded to develop the degraded layer 2a in a resist injection process performed previously.

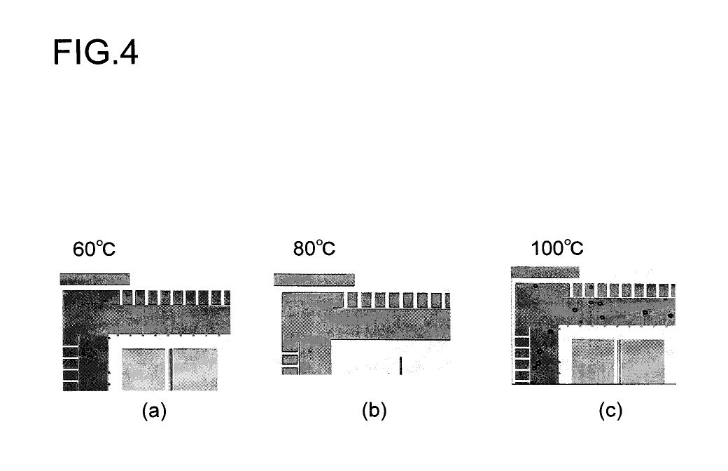

If the resist 2 having the degraded layer 2a developed in it as a result of ion injection is exposed to a temperature higher than that in a baking process performed for degassing during formation of a resist pattern, the vapor of an organic solvent inside the undegraded layer 2b causes the degraded layer 2a to rupture (a phenomenon called popping). This causes flakes from the degraded layer 2a to scatter, producing dents. FIG. 4 shows photographs of an example of popping as actually occurred in a resist pattern. In this example, baking was performed at 110° C. when a resist pattern was formed; then phosphorus ions were injected at 50 keV, 5.0×10¹⁵ ions/cm²; then the degraded layer was removed. FIG. 4(a) is a photograph taken when degraded layer removal was done at 60° C.; FIG. 4(b) is a photograph taken when degraded layer removal was done at 80° C.; and FIG. 4(c) is a photograph taken when degraded layer removal was done at 100° C. These photographs show occurrence of popping at 100° C. When popping occurs, it exposes down to the undegraded layer, making it impossible to selectively remove the degraded layer alone.

Degraded layer removal with radicals relies on a chemical reaction, and thus the higher the temperature, the faster the reaction progresses. Too high a temperature, however, causes popping as described above. Accordingly, the substrate temperature regulator 30 keeps the substrate 1 placed on it at a temperature that is equal to or higher than the temperature at or above which an activation energy enabling removal of the degraded layer 2a with radicals can be supplied but lower than the temperature at which popping occurs. To prevent popping, the temperature needs to be lower than the baking temperature during formation of the resist pattern. The baking temperature is generally 110° C. to 120° C., but cannot be uniquely determined because baking may be performed at a lower temperature to prevent a pattern shift resulting from dripping of resist ascribable to a rise in temperature.

When the temperature of the substrate 1 enters a predetermined range, gas is introduced through the gas introduction port 23, and simultaneously the high-frequency coil 28 is energized to subject the gas to plasma treatment. The introduced gas is one of nitrogen, oxygen, hydrogen, and water vapor, or a mixed gas of any combination of those. Plasma treatment is performed under a low pressure.

The ions generated by plasma treatment are shielded by the ion shielding plate 24, and do not enter the degraded layer removal portion 27. This suppresses the rise in the temperature of the substrate 1 resulting from contact with the ions, and thereby prevents occurrence of popping.

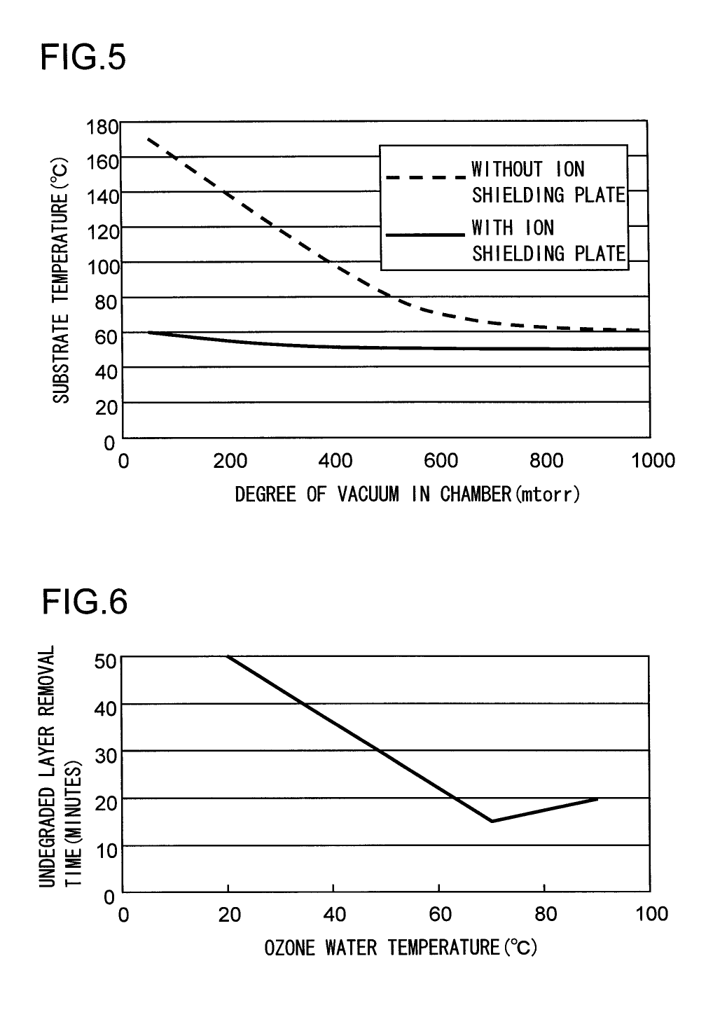

FIG. 5 is a graph showing the relationship between the degree of vacuum inside the vacuum chamber and the substrate temperature. These graphs show that the substrate temperature is better controlled with the ion shielding plate than without it. At higher degrees of vacuum, the ions are more likely to reach the substrate, and this combines with poor heat conduction to make a rise in substrate temperature more likely; at such higher degrees of vacuum, the effect of suppressing the rise in temperature is particularly notable.

The radicals generated by plasma treatment pass through the radical passage openings 25 in the ion shielding plate 24 to enter the degraded layer removal portion 27, where the radicals make contact with the substrate 1. The radicals remove the degraded layer 2a of the resist 2. In a case where a gas whose molecule contains a hydrogen atom is chosen as the target of plasma treatment, H radicals are generated, which allow effective removal of the degraded layer 2a. The treatment gas after removal of the degraded layer 2a is exhausted out of the vacuum chamber 20 through an unillustrated exhaust port.

The length of time of contact with the radicals is controlled according to the conditions of formation of the degraded layer 2a. Suppose a large part of the undegraded layer 2b is to be left unremoved. To leave a large part of the undegraded layer 2b unremoved, for example, the reacted gas that is exhausted during removal of the degraded layer 2a is analyzed by the gas analyzer 22, and according to the analysis results, the process is controlled.

In removal of the undegraded layer with radicals, the removal rate varies with the pressure (degree of vacuum) under which radicals are put in contact with the substrate 1, and the treatment performance varies accordingly. Under too low a pressure (too high a degree of vacuum), radicals are attracted by the vacuum pump 21, resulting in a low radical concentration in the degraded layer removal portion 27; thus removal of the degraded layer 2a does not progress. By contrast, under too high a pressure (too low a degree of vacuum), radicals react with other substances while moving from the plasma treatment portion 26 to the substrate 1, resulting in a low removal rate. In experiments, at pressures of 6.6 Pa to 667 Pa, plasma was generated, and removal of the degraded layer 2a with radicals was possible. An optimum pressure was about 133.3 Pa. Here, 6.6 Pa corresponds to a degree of vacuum of 50 mtorr, likewise 6.6 Pa corresponds to a degree of vacuum of 5 torr, and likewise 667 Pa corresponds to a degree of vacuum of 1 torr.

Upon completion of removal of the degraded layer 2a, the substrate 1 with a large part of the undegraded layer 2b left unremoved is taken out of the degraded layer removing unit 11, and is moved into the undegraded layer removal unit 12. The substrate 1 is placed on the table 41 of the undegraded layer removal portion 40, and then from the ozone water feed nozzle 42 ozone water is fed dropwise onto the substrate 1. The ozone water removes the undegraded layer 2b.

To increase the reactivity of ozone water and thereby expedite removal of the undegraded layer 2b, the ozone water is heated by the ozone water temperature regulator 44. FIG. 6 is a graph showing the relationship between the temperature of the ozone water and the removal time of the undegraded layer. An optimum range is from 70° C. to 80° C.

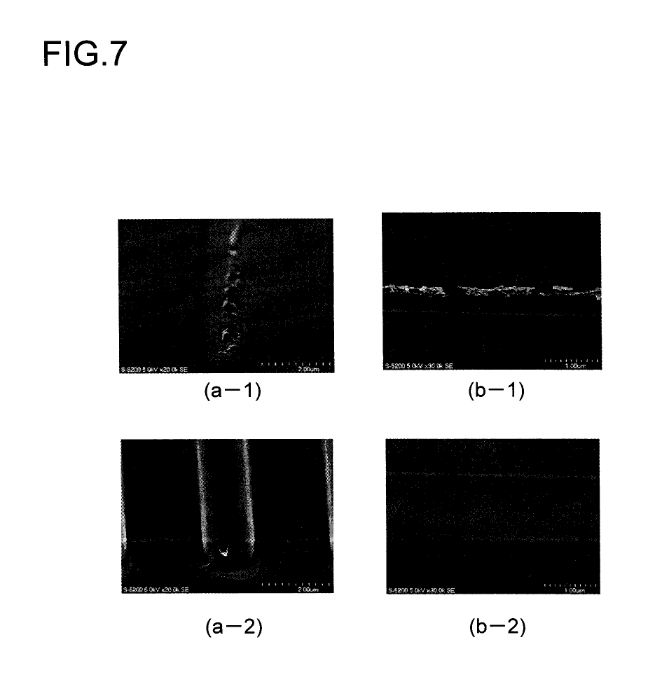

FIG. 7 shows photographs of an example of how the degraded layer and the undegraded layer are actually removed. Attempting to remove the undegraded layer without first selectively removing the degraded layer shown at (a-1) leaves a residue unremoved as shown at (b-1). First selectively removing the degraded layer as shown at (a-2) and then removing the undegraded layer leaves no residue as shown at (b-2).

A common semiconductor manufacturing process that does not employ the present invention goes through a process for removal of foreign matter by ammonia/hydrogen peroxide water cleaning (APM cleaning, SC1 cleaning) and a process for removal of metal components by hydrochloric acid/hydrogen peroxide water cleaning (HPM cleaning, SC2 cleaning) before proceeding to a cleaning process using hydrogen fluoride (HF) and then to a diffusion process. A method according to the present invention permits resist removal to be completed with no residue left unremoved, and thus makes it possible to proceed thereafter directly to the cleaning process using hydrogen fluoride and then to the diffusion process. It is thus possible to realize a semiconductor manufacturing method that uses little chemicals and that has little effect on the environment.

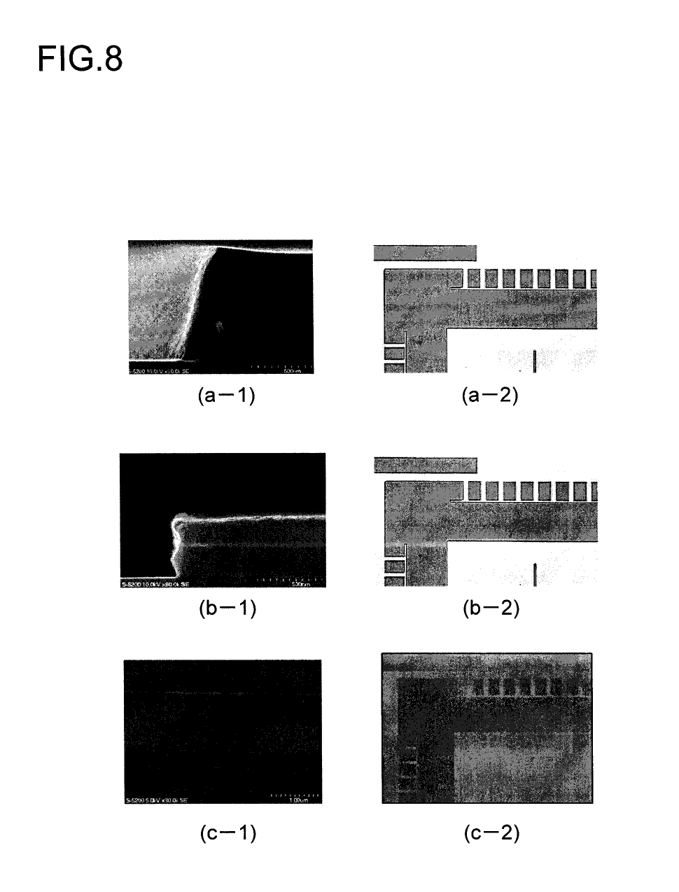

FIG. 8 shows photographs taken in resist removal experiments conducted with an apparatus embodying the present invention. The substrate used in the experiments was a silicon wafer for a semiconductor; it had a resist pattern formed on its surface, and had undergone ion injection at a high concentration under the conditions of ³¹P⁺, 50 keV, and 5.0×10¹⁵ ions/cm². A resist having undergone such high-concentration ion injection has its surface degraded and hardened, and is generally considered to be difficult to remove. The condition before resist removal is shown at (a-1) and (a-2). At (a-1) is a cross-sectional photograph of the resist, and at (a-2) is a plan-view photograph of the resist pattern.

The gas used for plasma treatment was a mixed gas of H₂ and N₂, having 4% of H₂ mixed in N₂. With the substrate temperature at 100° C., the vacuum chamber pressure at 133.3 Pa, and the plasma power at 2 000 W, in the presence of the ion shielding plate, degraded layer removal operation was performed for 360 seconds. After this process, the condition was as shown at (b-1) and (b-2) in FIG. 8. At (b-1) is a cross-sectional photograph of the resist, and at (b-2) is a plan-view photograph of the resist pattern. The degraded layer alone was removed selectively, without causing popping.

After degraded layer removal, the substrate was put in contact with 90 ppm ozone water at 80° C. to remove the undegraded layer. The condition after undegraded layer removal is shown at (c-1) and (c-2) in FIG. 8. At (c-1) is a cross-sectional photograph of the resist, and at (c-2) is a plan-view photograph of the resist pattern. The undegraded layer was removed with no residue left unremoved.

Experiments conducted by use of, instead of a mixed gas of H₂ and N₂, a mixed gas of H₂ and He having 4% of H₂ mixed in He yielded similar results as those given above.

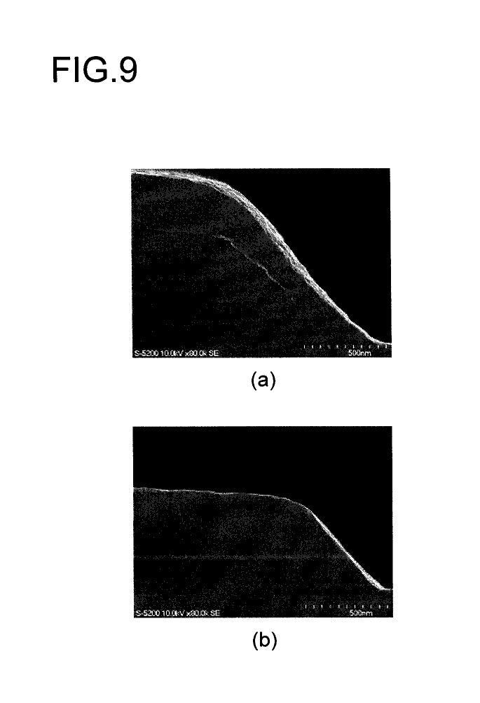

FIG. 9 shows photographs taken in resist removal experiments conducted with an apparatus embodying the present invention, by use of water vapor. Degraded layer removal was performed under the following conditions: water vapor of pure water was generated at a rate of 100 ml/min, and was then subjected to plasma treatment with the vacuum chamber pressure at 133.3 Pa and the plasma power at 2 000 W, in the presence of the ion shielding plate. The generated radicals were put in contact with the substrate at a temperature of 40° C. for 180 seconds to remove the degraded layer. FIG. 9 shows, at (a), the condition before degraded layer removal and, at (b), the condition after degraded layer removal. The photograph at (b) shows that the undegraded layer was left unremoved without causing popping. Although no photograph is given, the undegraded layer was removed with no residue left unremoved.

The embodiment by way of which the present invention has been described hereinbefore is in no way meant to limit the scope of the present invention, which can therefore be carried out with any modification or variation made without departing from the spirit of the present invention.

### INDUSTRIAL APPLICABILITY

The present invention finds wide application in processes for removing resist from a substrate.

1-18. (canceled)

19. A resist removal method for removal of surface-degraded resist from a substrate, comprising:
a step of removing the resist by putting, in contact with the substrate, radicals generated through plasma treatment of one of nitrogen, oxygen, hydrogen, and water vapor or a mixed gas of any combination thereof under a low pressure; and
a step of removing the resist by putting ozone water in contact with the substrate.

20. The resist removal method according to claim 19,
wherein the step of resist removal using the radicals precedes the step of resist removal using the ozone water.

21. The resist removal method according to claim 20,
wherein the step of resist removal using the radicals is mainly for removing a degraded layer at a surface of the resist, and the step of resist removal using the ozone water is for removing an undegraded layer inside the resist.

22. The resist removal method according to claim 20,
wherein, in the step of resist removal using the radicals, a length of time of contact with the radicals is controlled according to a condition of formation of the degraded layer at the surface of the resist such that a large part of the undegraded layer is left unremoved.

23. The resist removal method according to claim 20,
wherein, in the step of resist removal using the radicals, process control is performed according to a result of analysis of a reacted gas exhausted during resist removal such that a large part of the undegraded layer is left unremoved.

24. The resist removal method according to claim 19,
wherein, in the step of resist removal using the radicals, a temperature of the substrate is kept equal to or higher than a temperature at or above which an activation energy enabling removal of the degraded layer using radicals can be supplied but lower than a temperature at which popping occurs.

25. The resist removal method according to claim 19,
wherein, in the step of resist removal using the radicals, an ion shielding plate is disposed between a plasma treatment portion and the substrate to prevent ions in generated plasma from making contact with the substrate.

26. The resist removal method according to claim 19,
wherein, in the step of resist removal using the radicals, a pressure of contact between the substrate and the radicals is 6.6 Pa or more.

27. The resist removal method according to claim 19,
wherein, in the step of resist removal using the radicals, a pressure of contact between the substrate and the radicals is 667 Pa or less.

28. The resist removal method according to claim 19,
wherein, in the step of resist removal using the ozone water, the ozone water is heated and used.

29. A semiconductor manufacturing method in which the substrate that has gone through the resist removal method according to claim 19 is cleaned with hydrogen fluoride and is then sent to a diffusion process.

30. A resist removal method for removal of surface-degraded resist from a substrate, comprising:
a step of removing the resist by putting, in contact with the substrate, radicals generated through plasma treatment of a gas whose molecule contains a hydrogen atom; and
a step of removing the resist by putting ozone water in contact with the substrate.

31. The resist removal method according to claim 30,
wherein the step of resist removal using the radicals precedes the step of resist removal using the ozone water.

32. The resist removal method according to claim 31,
wherein the step of resist removal using the radicals is mainly for removing a degraded layer at a surface of the resist, and the step of resist removal using the ozone water is for removing an undegraded layer inside the resist.

33. The resist removal method according to claim 31,
wherein, in the step of resist removal using the radicals, a length of time of contact with the radicals is controlled according to a condition of formation of the degraded layer at the surface of the resist such that a large part of the undegraded layer is left unremoved.

34. The resist removal method according to claim 31,
wherein, in the step of resist removal using the radicals, process control is performed according to a result of analysis of a reacted gas exhausted during resist removal such that a large part of the undegraded layer is left unremoved.

35. The resist removal method according to claim 30,
wherein, in the step of resist removal using the radicals, a temperature of the substrate is kept equal to or higher than a temperature at or above which an activation energy enabling removal of the degraded layer using radicals can be supplied but lower than a temperature at which popping occurs.

36. The resist removal method according to claim 30,
wherein, in the step of resist removal using the radicals, an ion shielding plate is disposed between a plasma treatment portion and the substrate to prevent ions in generated plasma from making contact with the substrate.

37. The resist removal method according to claim 30,
wherein, in the step of resist removal using the radicals, a pressure of contact between the substrate and the radicals is 6.6 Pa or more.

38. The resist removal method according to claim 30,
wherein, in the step of resist removal using the radicals, a pressure of contact between the substrate and the radicals is 667 Pa or less.

39. The resist removal method according to claim 30,
wherein, in the step of resist removal using the ozone water, the ozone water is heated and used.

40. A semiconductor manufacturing method in which the substrate that has gone through the resist removal method according to claim 30 is cleaned with hydrogen fluoride and is then sent to a diffusion process.

41. A resist removal apparatus for removal of surface-degraded resist from a substrate, comprising:
a gas supply portion supplying one of nitrogen, oxygen, hydrogen, and water vapor or a mixed gas of any combination thereof;
a plasma treatment portion subjecting the gas supplied from the gas supply portion to plasma treatment to generate radicals;
a degraded layer removal portion putting the radicals in contact with the substrate to mainly remove a degraded layer at a surface of the resist;
an ozone water generation portion; and
an undegraded layer removal portion putting ozone water supplied from the ozone water generation portion in contact with the substrate to mainly remove an undegraded layer of the resist.

42. The resist removal apparatus according to claim 41,
wherein operation of the degraded layer removal portion is controlled by controlling a length of time of contact with the radicals according to a condition of formation of the degraded layer at the surface of the resist or by performing process control according to a result of analysis of a reacted gas exhausted during resist removal.

43. The resist removal apparatus according to claim 41,
wherein a temperature of the substrate in the degraded layer removal portion is kept equal to or higher than a temperature at or above which an activation energy enabling removal of the degraded layer using radicals can be supplied but lower than a temperature at which popping occurs.

44. The resist removal apparatus according to claim 41,
wherein an ion shielding plate is disposed between the plasma treatment portion and the substrate in the degraded layer removal portion to prevent ions in generated plasma from making contact with the substrate.

45. The resist removal apparatus according to claim 41,
a temperature regulator regulating a temperature of the ozone water supplied to the undegraded layer removal portion.

46. A resist removal apparatus for removal of surface-degraded resist from a substrate, comprising:
a gas supply portion supplying a gas whose molecule contains a hydrogen atom;
a plasma treatment portion subjecting the gas supplied from the gas supply portion to plasma treatment to generate radicals;
a degraded layer removal portion putting the radicals in contact with the substrate to mainly remove a degraded layer at a surface of the resist;
an ozone water generation portion; and
an undegraded layer removal portion putting ozone water supplied from the ozone water generation portion in contact with the substrate to mainly remove an undegraded layer of the resist.

47. The resist removal apparatus according to claim 46,
wherein operation of the degraded layer removal portion is controlled by controlling a length of time of contact with the radicals according to a condition of formation of the degraded layer at the surface of the resist or by performing process control according to a result of analysis of a reacted gas exhausted during resist removal.

48. The resist removal apparatus according to claim 46,
wherein a temperature of the substrate in the degraded layer removal portion is kept equal to or higher than a temperature at or above which an activation energy enabling removal of the degraded layer using radicals can be supplied but lower than a temperature at which popping occurs.

49. The resist removal apparatus according to claim 46,
wherein an ion shielding plate is disposed between the plasma treatment portion and the substrate in the degraded layer removal portion to prevent ions in generated plasma from making contact with the substrate.

50. The resist removal apparatus according to claim 46,
a temperature regulator regulating a temperature of the ozone water supplied to the undegraded layer removal portion.
